(19) United States
(12) Patent Application Publication
(10) Pub. No.: US 2015/0109031 A1
(43) Pub. Date: Apr. 23, 2015

(54) RC-IGBT WITH FREEWHEELING SIC DIODE

(71) Applicant: ABB Technology AG, Zurich (CH)

(72) Inventor: Munaf Rahimo, Uezwil (CH)

(73) Assignee: ABB TECHNOLOGY AG, Zurich (CH)

(21) Appl. No.: 14/519,605

(22) Filed: Oct. 21, 2014

(30) Foreign Application Priority Data
Oct. 22, 2013 (EP) 13189728.2

(51) Int. Cl. H03K 3/012; H03K 17/74; H03K 17/66

(52) U.S. Cl. CPC H03K 3/012; H03K 17/66; H03K 17/74
USPC 327/109

(57) ABSTRACT

A semiconductor module as disclosed can include a reverse conducting transistor, with a gate, a collector and an emitter providing a reverse conducting diode between collector and emitter; at least one freewheeling diode connected antiparallel to the transistor having a forward voltage drop higher than the reverse conducting diode during a static state; and a controller to turn the transistor on and off. The controller can apply a pulse to the transistor gate before the reverse conducting diode enters a blocking state, such that when the reverse conducting diode enters the blocking state, a forward voltage drop of the reverse conducting diode is higher than of the at least one freewheeling diode.

### RELATED APPLICATION

This application claims priority under 35 U.S.C. §119 to European Patent Application No. 13189728.2 filed in Europe on Oct. 22, 2013, the entire content of which is hereby incorporated by reference in its entirety.

### FIELD

The present disclosure relates to the field of power semiconductors. For example, the disclosure relates to a semiconductor module and a method for switching a reverse conducting transistor on such a module.

### BACKGROUND INFORMATION

For example, high power inverters, rectifiers and other electrical high power equipment can include half-bridge modules, which can have two semiconductor switches connected in series for connecting a DC side with an AC side of the equipment. In such a case, the semiconductor switch is blocking in its reverse direction (i.e., a direction reverse to a direction adapted for conducting a current, when the semiconductor switch is turned on); it is possible to connect a freewheeling diode antiparallel to the semiconductor switch.

Some semiconductor switches already provide such a reverse conducting current path on their own, such as with a reverse conducting diode that is integral with the semiconductor switch. An example for such switches is an RC-IGBT or for example, a BIGT, such as described in EP 2 249 392 A2.

However, BIGTs in reverse conducting diode mode may suffer from higher conduction losses (e.g., based on the forward voltage drop V_{f}) with positive gate values. Furthermore, to optimize a BIGT for lower diode mode switching losses, a lifetime control may be employed that can result in higher diode and transistor conduction losses (based on V_{f} and V_{CE}).

It is also known to reduce diode switching losses of a BIGT by so-called MOS control, a special switching scheme of the transistor before the reverse conducting diodes enter a blocking state. For example, the article Rahimo et. al. “A high current 3300 V module employing reverse conducting IGBTs setting a new benchmark in output power capability”, Proceedings of 20th International Symposium on Power Semiconductor Device & ICs (18 to 22 May 2008) describes a technique for controlling an RC-IGBT in reverse conducting mode.

A method for controlling a vertical type MOSFET arranged in a bridge circuit is known from US 2008/0265975 A1, wherein a forward voltage of a built-in diode is controlled by applying a gate pulse to a gate of the MOSFET, thereby allowing to reduce diode power losses.

On the other hand, SiC unipolar diodes may be used as freewheeling diodes but can suffer from oscillatory behavior and high switching losses at higher temperatures. In addition, the cost of a SiC device can make it difficult to compensate this behavior with larger areas.

### SUMMARY

A semiconductor module is disclosed, comprising: a reverse conducting transistor with a gate, a collector and an emitter providing a reverse conducting diode between the collector and emitter; at least one freewheeling diode connected antiparallel to the transistor and having a forward voltage drop higher than the reverse conducting diode during a static state; and a controller for connecting the gate with an electrical potential to turn the transistor on and off; wherein the controller is configured for applying a gate pulse of positive electrical potential to the gate of the transistor before the reverse conducting diode enters a blocking state, such that in a dynamic state, in which the reverse conducting diode enters the blocking state, a forward voltage drop of the reverse conducting diode is higher than that of the at least one freewheeling diode; wherein the reverse conducting transistor is a RC-IGBT or a BIGT, and wherein the at least one freewheeling diode includes a SiC diode.

A method is also disclosed for switching a reverse conducting transistor and at least one freewheeling diode connected antiparallel to the transistor, wherein the at least one freewheeling diode has a forward voltage drop higher than a reverse conducting diode of the transistor during a static state, the method comprising: determining that the reverse conducting diode will switch from a conducting state into a blocking state; and applying a gate pulse of positive electrical potential to a gate of the transistor before the reverse conducting diode enters a blocking state, such that in a dynamic state, in which the reverse conducting diode enters the blocking state, a forward voltage drop of the reverse conducting diode is higher than that of the at least one freewheeling diode, wherein the reverse conducting transistor is a RC-IGBT or a BIGT, and wherein the at least one freewheeling diode includes a SiC diode.

### BRIEF DESCRIPTION OF THE DRAWINGS

The subject-matter disclosed herein will be explained in more detail in the following text with reference to exemplary embodiments which are illustrated in the attached drawings, wherein:

FIG. 1 schematically shows an exemplary high power circuit layout of a semiconductor module according to an exemplary embodiment disclosed herein;

FIG. 2 schematically shows an exemplary circuit board layout of the semiconductor module of FIG. 1;

FIG. 3 shows an exemplary diagram with gate voltages for illustrating a method for switching the module of FIGS. 1 and 2; and

FIG. 4 shows an exemplary diagram with turn-on currents illustrating an adjustment of freewheeling diodes for the module of FIGS. 1 and 2.

The reference symbols used in the drawings, and their meanings, are listed in summary form in the list of reference symbols. In principle, identical parts are provided with the same reference symbols in the figures.

### DETAILED DESCRIPTION

A semiconductor switch is disclosed that may be employed in a high power half-bridge, which can have low switching losses, for example, at high temperatures.

For example, a semiconductor module is disclosed which can include a PCB housing and/or carrying semiconductor devices such as transistors, diodes and circuitry of a controller as described herein.

According to an exemplary embodiment, the semiconductor module can include a reverse conducting transistor with a gate, collector and emitter providing a reverse conducting diode between the collector and emitter, and at least one freewheeling diode connected antiparallel to the transistor having a forward voltage drop higher than the reverse conducting diode during a static state (in which a static current may flow through both diodes).

The reverse conducting transistor can be a RC-IGBT (reverse conducting insulated gate bipolar transistor), such as a BIGT (bi-mode insulated gate transistor). The at least one freewheeling diode may be at least one SiC diode, which may be adjusted to have a forward voltage drop as already described. For example, the semiconductor module may include one, two or more reverse conducting transistors and/or may include one or more than one freewheeling diode connected antiparallel with one of the transistors. It may be the case that the transistor is provided on one die and the at least one freewheeling diode can be provided on an additional die. The reverse conducting diode can be integral with the IGBT of the RC-IGBT. The combination of a RC-IGBT or BIGT with a SiC diode can have an exemplary advantage that the freewheeling diode has a forward voltage drop higher than the reverse conducting diode of the semiconductor switch. Thus a combination of these types of semiconductors can have a technical effect that applying a positive gate pulse to a gate of the transistor prior to reverse recovery leads to a redirection of current before reverse recovery.

Furthermore, the semiconductor module can include a controller or gate unit for connecting the gate with an electrical potential to turn the transistor on and off. The controller can be configured (i.e., adapted) for applying a pulse of opposite electrical potential to the gate of the transistor before the reverse conducting diode enters a blocking state, such that in a dynamic state, in which the reverse conducting diode enters the blocking state, a forward voltage drop of the reverse conducting diode is higher than of the at least one freewheeling diode.

The reverse conducting transistor, such as the reverse conducting diode, may have higher losses than the freewheeling diode during a dynamic state or dynamic phase in which both types of diodes conduct a fast changing current and/or switch between a conducting state and a blocking state. Furthermore, with the application of the gate pulse, the stored charges in the reverse conducting diodes may be depleted from the transistor, which may lower the losses of the reverse conducting diode during the dynamic phase and for example, during switching from the conducting state into the blocking state.

Exemplary methods are also disclosed for switching a reverse conducting transistor and at least one freewheeling diode connected antiparallel to the transistor, wherein the at least one freewheeling diode has a forward voltage drop higher than the reverse conducting diode during a static state. For example, the method may be carried out by a controller of a semiconductor module, for example as already described, and as described in the following.

Those skilled in the art will appreciate that features of the method as described herein may be features of the semiconductor module as described herein, and vice versa.

According to an exemplary embodiment, a disclosed method can include determining that the reverse conducting diode will switch from a conducting state into a blocking state and applying a pulse of opposite electrical potential to the gate of the transistor before the reverse conducting diode enters a blocking state, such that in a dynamic state, in which the reverse conducting diode enters the blocking state, a forward voltage drop of the reverse conducting diode is higher than that of the at least one freewheeling diode.

The application of the gate pulse may be referred to as MOS control. For example, a combination of antiparallel SiC diodes with a MOS control of a BIGT may provide reduced switching losses during the operation of the semiconductor module.

Additionally, to reduce losses of the reverse conducting diode in its conducting state, the transistor may be kept in a turned-off state by a corresponding control of the gate. Furthermore, before the diodes enter a blocking state, the transistor can be turned-on for a short time with a short gate pulse.

According to an exemplary embodiment, the controller can be configured (i.e., adapted) for and/or the method can include: applying a negative potential to the gate, when the reverse conducting diode is in a conducting state, and applying a positive potential to the gate during the gate pulse. Those skilled in the art will appreciate that the positive and/or negative potential may have the same voltages as the potentials that are used for turning the transistor on and off. During conduction of the reverse conducting diode, the gate emitter voltage may be kept negative to store the charge in the device. As the diode reverse conducting is about to turn off, a short positive gate emitter pulse may be applied to the reverse conducting diode to minimize the stored charge.

According to an exemplary embodiment, during the static state, in which a static current may flow through the reverse conducting diode and the at least one freewheeling diode, the resistance of the reverse conducting diode is smaller than the resistance of the at least one freewheeling diode. With the gate pulse and the internal resistance of the at least one freewheeling diode, the amount of current flowing through the reverse conducting diode may be adjusted with respect to the amount of current flowing through the freewheeling diodes. The gate pulse may increase the internal resistance of the reverse conducting diode during the dynamic state and thus the current may be redirected from the reverse conducting diode to the freewheeling diode.

According to an exemplary embodiment, the at least one freewheeling diode antiparallel to the transistor can be adjusted to the transistor so that in a predefined temperature range the switching losses of the semiconductor module are minimized. For example, the characteristics of the at least one freewheeling diode may be adjusted to the characteristics of the transistor by choosing an appropriate number of equally designed diodes connected antiparallel with the transistor. For example, the number of freewheeling diodes may be chosen such that their collective internal resistance becomes lower than the internal resistance of the reverse conducting diode after the gate pulse.

According to an exemplary embodiment, the at least one freewheeling diode antiparallel to the transistor is adjusted such that in a predefined temperature range during the static phase at least 60% of the current flows through the reverse conducting diode, and/or during the dynamic phase at least 60% of the current flows through the at least one freewheeling diode.

According to an exemplary embodiment, the temperature range for which the at least one freewheeling diode is adjusted is 50° C. to 200° C. For example, at high temperatures, SiC diodes may have rather high conduction losses and the overall losses of the semiconductor module may be reduced by adjusting the characteristics of the diodes and the transistor such that the losses at high temperatures are minimized.

According to an exemplary embodiment, the semiconductor module can include a first reverse conducting transistor connected in series with a second reverse conducting transistor, wherein a first DC input is provided by a free end of the first transistor, a second DC input is provided by a free end of the second transistor and a phase output is provided between the series connected transistors, wherein the least one freewheeling diode is connected antiparallel to the first reverse conducting transistor. The semiconductor module can include a half-bridge of two RC-IGBTs or two BIGTs that may be used for converting a DC voltage into an AC voltage and vice versa. One or both of the transistors may be provided with one or more freewheeling diodes.

According to an exemplary embodiment, the controller can be configured (i.e., adapted) for and/or the method comprises: determining that the reverse conducting diode of the first transistor will switch from a conducting into a blocking state by receiving a switch command for the second transistor. The switch command may be a turn-off command that, for example, is received from a central controller. The usage of MOS control with a transistor with an antiparallel freewheeling diode may be executed by the gate unit (controller) of a half bridge for one of the transistors, when the other one is turned off.

In the case of a half-bridge with two RC-IGBTs or BIGTs, before one IGBT is switched conducting, a MOS control pulse is applied to the other one.

According to an exemplary embodiment, the controller can be configured (i.e., adapted) for and/or the method can include: switching the second transistor from a turned-off state into a turned-on state by turning a negative potential at the gate of the second transistor into a positive potential at the gate after receiving the switch command.

According to an exemplary embodiment, a pulse length of the gate pulse applied to the first transistor is at least 10% of the length of the turned-off state of the second transistor. For example, the length of the gate pulse may be substantially smaller than the turn-off and turn-on states of the transistor.

According to an exemplary embodiment, the controller can be configured (i.e., is adapted) for and/or the method can include: waiting a blocking time period after the gate pulse before switching the second transistor into a turned-off state. To prevent a short-circuiting of the half-bridge and/or for adjusting the depletion of the reverse conducting diode, the turn-on of the second transistor may have a time offset (the blocking time period) with respect to the end of the gate pulse.

These and other aspects disclosed herein will be more apparent from and elucidated with reference to the embodiments of the drawings as described hereinafter.

FIG. 1 shows an exemplary circuit layout of high power semiconductors of a semiconductor module 10. Those skilled in the art will appreciate that a high power semiconductor may be a semiconductor for processing an exemplary current of more than 10 A and/or a voltage of more than 1000 V. The exemplary module 10 can include two BIGTs 12a, 12b connected in series and forming a half-bridge. The first transistor 12 provides a DC+ input 14 at its collector 16a and is connected with its emitter 18a with the collector 16b of the second transistor 12b, which provides an DC− input 20 at its emitter 18b. A load output 22 is provided between the two transistors 12a, 12b (i.e., by the emitter 18a and the collector 16b).

Each of the transistors 12a, 12b can include an internal reverse conducting diode 24a, 24b that is indicated in the circuit symbol of the both transistors and a gate 26a, 26b that is adapted for turning the respective transistor 12a, 12b on and off.

A RC-IGBT can include a freewheeling diode and an insulated gate bipolar transistor on a common wafer. The IGBT (insulated gate bipolar transistor) can include a collector side and an emitter side opposite to the collector side of the wafer. Part of the wafer forms an (n−) doped base layer with a first doping concentration and a base layer thickness. The base layer thickness is the maximum vertical distance between the collector and emitter side of that part of the wafer with the first doping concentration. An n doped source region, a p doped base layer and a gate electrode are arranged on the emitter side. The gate electrode may be a planar or a trench gate electrode. The reverse-conducting semiconductor device can include an electrically active region, which active region is an area within the wafer, which includes and is arranged below the source region, base layer and the gate electrode.

A first n doped layer having higher doping concentration than the first doping concentration and a p doped collector layer are alternately arranged on the collector side. The first layer can include at least one first region, wherein each first region has a first region width. Any region has a region width and a region area, which is surrounded by a region border, wherein a shortest distance is the minimum length between a point within the region area and a point on the region border. Each region width is defined as two times the maximum value of any shortest distance within the region.

A BIGT can have, in addition to the features of a RC-IGBT, the following features. The collector layer can include at least one second region, wherein each second region has a second region width, and at least one third region, wherein each third region has a third region width. Each third region area is an area, which border is defined by any two surrounding first regions having a distance bigger than two times the base layer thickness. The at least one second region is that part of the second layer, which is not the at least one third region. The at least one third region is arranged in a central part of the active region in such a way that there is a minimum distance between the third region border to the active region border of at least once the base layer thickness. The sum of the areas of the at least one third region is, for example, between 10% and 30% of the active region. Each first region width is smaller than the base layer thickness. The third region may have a star shape with three protrusions forming a tri-star, four protrusions forming a cross or five or more protrusions. Further details of a BIGT may be found in the international patent application EP 2 249 392 A2, the content of which document, particularly concerning the definition of a reverse conducting IGBT having small large p doped second regions and at least one large third region on the collector side in the above mentioned way (i.e., of a BIGT), is incorporated herein by reference in its entirety. Further details defining such an BIGT can be found in EP 2 249 392 A2.

When the gate 26a, 26b of the transistor 12a, 12b is set to a specific positive turn-on voltage/potential, a positive current may flow from the collector 16a, 16b to the emitter 18a, 18b. When the gate 26a, 26b is set to a specific negative turn-off voltage/potential, the transistor blocks positive currents from the collector 16a, 16b to the emitter 18a, 18b. In any case, the diode 24a, 24b allows a positive current flowing from the emitter 18a, 18b to the collector 16a, 16b.

The module 10 can include one or more freewheeling SiC diodes 28a, 28b connected antiparallel to the transistor 12a, 12b and parallel to the reverse conducting diode 24a, 24b. Like the diode 24a, 24b, the diodes 28a, 28b allow a positive current flowing from the emitter 18a, 18b to the collector 16a, 16b.

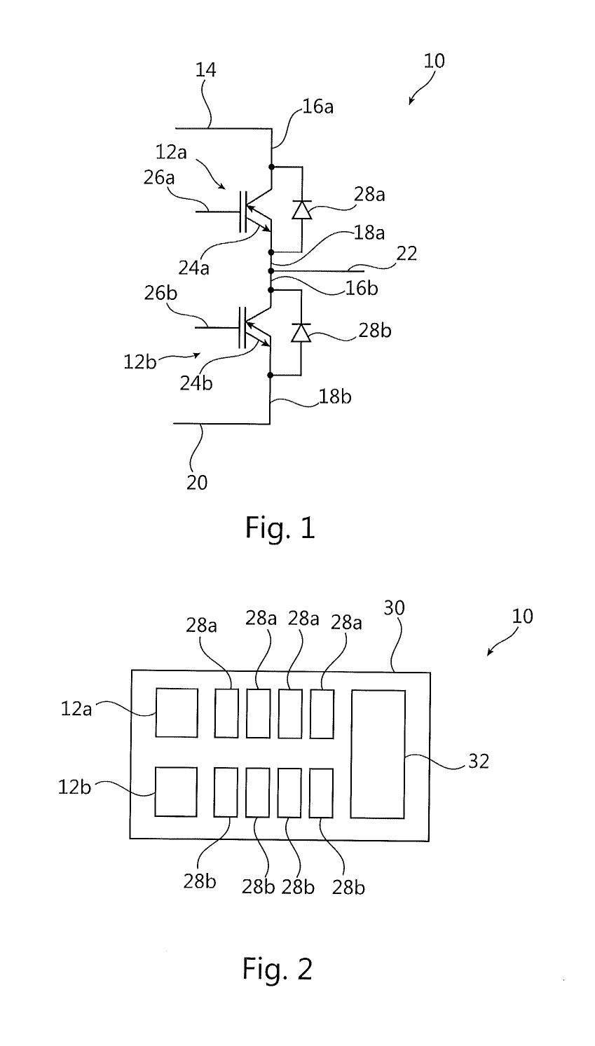

FIG. 2 shows a schematic board layout of the module 10. The two transistors 12a, 12b may be carried by a PCB 30. The PCB 30 furthermore carries a number of freewheeling diodes 28a, 28b for each transistor 12a, 12b (in the shown example four diodes 28a, 28b per transistor 12a, 12b) and a controller 32 or gate unit 32.

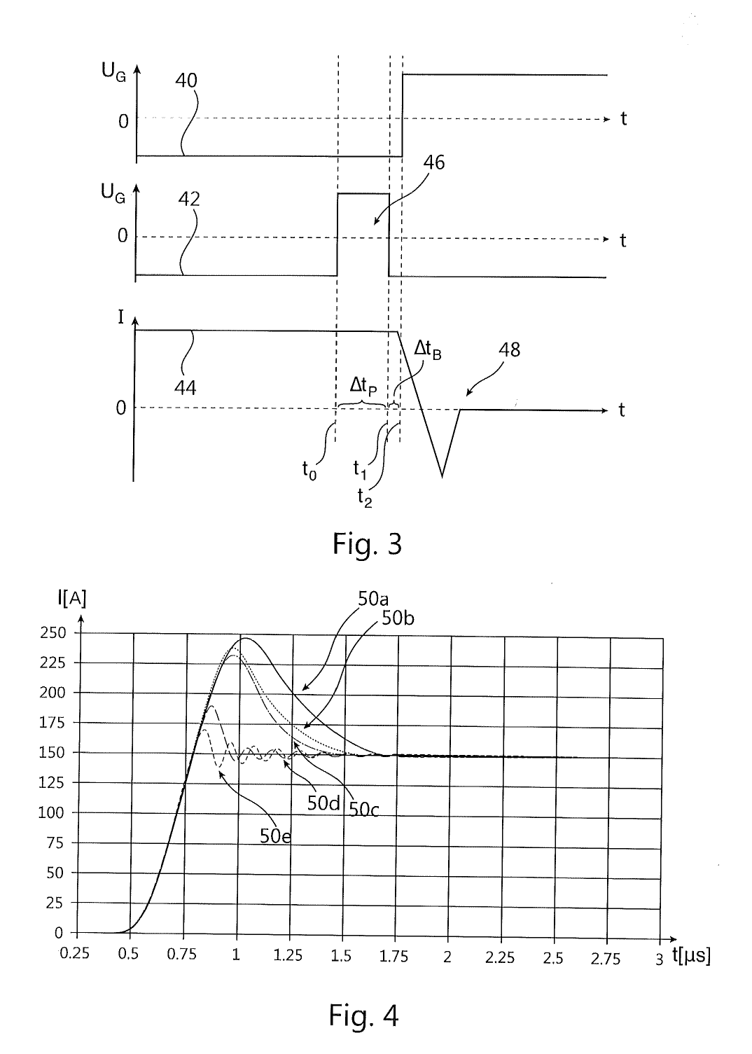

FIG. 3 shows the gate voltages 40, 42 at the transistors 12a, 12b and the current 44 through the reverse conducting diode 24b over time. FIG. 3 illustrates an exemplary method that may be performed by the controller 32.

Line 40 shows an exemplary voltage applied to the gate 26b of the second transistor 12b and line 42 shows the voltage applied to the gate 26a of the first transistor 12a. Line 44 shows the current flowing through the reverse conducting diode 28a.

Initially, a negative gate voltage 40, 42 (for example −15 V) is applied to both gates 26a, 26b.

For the BIGT 12a, during an exemplary normal diode conduction mode (the static state), the forward voltage drop V_{f} over the BIGT 12a is much lower than for the SiC diode 28a since the gate is either 0 or negative. This may be improved by having for the BIGT 12a more area and/or less lifetime control while in addition the SiC diode 28a may have a higher forward voltage drop V_{f} at higher temperatures due to its uni-polar action. Hence, only a small current flows through the SiC, diode 28a.

In other words, in the static state, in which a static current flows through the reverse conducting diode 24a and the freewheeling diode 28a, the resistance of the reverse conducting diode 24a is smaller than the resistance of the at least one freewheeling diode 28a.

After that, before time point t₀, the controller 32 determines that the reverse conducting diode 28a will switch from a conducting state into a blocking state, for example by receiving a turn-on command for the transistor 12b.

At time point t₀, the controller 32 reverses the voltage 42 at the gate 26a to a positive potential/voltage (for example +15 V) and reverses the voltage back 42 to the negative potential/voltage at time point t₁.

In such a way, a gate pulse 46 is applied to the gate 26a before the reverse conducting diode 24a enters the blocking state. Before reverse recovery, the gate voltage of the BIGT 12a is increased to a positive potential resulting in a much higher forward voltage drop V_{f} due to the shorting of the P-well cells which act as the anode of the diode 24a. This will re-direct current through the SiC diode 28a and hence at reverse recovery and by applying the gate pulse 46 (i.e., using MOS control action), the peak recovery current 48 can be very low resulting in lower losses and the BIGT diode 28a will still provide a soft tail.

To achieve a rather high forward voltage drop under a positive gate potential, a trench BIGT 12a, 12b may be used.

The time period Δt_{P} between t0 and t1 (i.e., the length of the gate pulse) may for example, be about 10 μs.

After the gate pulse 46, the controller waits for a blocking time period Δt_{B} before it switches the gate voltage 40 of the second transistor to positive potential/voltage for turning on the transistor 12a. The blocking time period Δt_{B} may be smaller than, for example, 5 μs.

The method can combine a BIGT (or more general a RC-IGBT) and a SiC unipolar diode with a MOS control gate pulse prior to reverse recovery to redirect the current before reverse recovery.

The combination of the correspondingly adjusted freewheeling diode 28a with MOS gate control may result in exemplary advantages in terms of lower switching losses and softness. The method and device may combine the optimum performance of a Si BIGT 12a, 12b and a SiC diode 28a, 28b to achieve the best trade-offs in terms of losses and softness.

With such a combination, lower forward voltage drops, switching losses and a softer performance may be achieved. In addition, less SiC area for the diodes 28a, 28b may be required compared to a standard approach for lower costs.

FIG. 4 shows a diagram with exemplary mirrored reverse recovery currents for different combinations of a BIGT 12a, 12b with different numbers of SiC diodes 28, 28b to illustrate how the characteristics of the transistors and the freewheeling diodes 28a, 28b may be adjusted.

The currents 50a, 50b, 50c, 50d, 50e over time are based on tests that were carried out for 1.7 kV BIGTs 12a, 12b and four SiC diodes 28a, 28b. In principle, the currents 50a, 50b, 50c, 50d, 50e are the sum of the current 44 of FIG. 3 and the current through the transistor 12b.

The tests were done at room temperature because it can be considered a best case to demonstrate the concept from the forward voltage drop values V_{f} given for these devices. For such tests, there is still a lot of sharing under different modes.

Following table shows the results.

| | | switching | forward voltage drop |
|---|---|---|---|
| combination | Δt_{B} | losses | (dependent on gate voltage) |
| only Si BIGT, | 10 μs | 58 mJ | at 25° C.: 2.5 V (0 V) to 3.7 V |
| current 50a | | | (15 V) |
| only Si BIGT, | 1 μs | 45 mJ | at 125° C.: 2.95 V (0 V) to |
| current 50b | | | 3.75 V (15 V) |
| Si BIGT and 4 SiC | 10 μs | 41 mJ | at 25° C.: 1.8 V (0 V) to 2.3 V |
| diodes, current 50c | | | (15 V) |
| Si BIGT and 4 SiC | 1 μs | 21 mJ | at 125° C.: 2.25 V (0 V) to |
| diodes, current 50d | | | 3.25 V (15 V) |
| only 4 SiC diodes, | | 17 mJ | at 25° C.: 2.4 V |
| current 50e | | | at 125° C.: 4.25 V |

The current 50d shows an exemplary optimum combination resulting in very small losses and a soft tail.

While exemplary embodiments disclosed have been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practising the claimed invention, from a study of the drawings, the disclosure, and the appended claims. In the claims, the word “comprising” does not exclude other elements or steps, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

10 semiconductor module
12a, 12b transistor
14 DC+ input
16a, 16b collector
18a, 18b emitter
20 DC− input
22 load output
24a, 24b reverse conducting internal diode
26a, 26b gate
28a, 28b freewheeling diode
30 PCB
32 controller
40 gate voltage
42 gate voltage
44 current through reverse conducting diode
46 gate pulse
48 peak recovery current
t₀ start of gate pulse
t₁ end of gate pulse
t₂ start of turn-on pulse
Δt_{P} gate pulse length
Δt_{B} blocking time period
50a to 50e recovery currents

1. A semiconductor module, comprising:
a reverse conducting transistor with a gate, a collector and an emitter providing a reverse conducting diode between the collector and emitter;
at least one freewheeling diode connected antiparallel to the transistor and having a forward voltage drop higher than the reverse conducting diode during a static state; and
a controller for connecting the gate with an electrical potential to turn the transistor on and off;
wherein the controller is configured for applying a gate pulse of positive electrical potential to the gate of the transistor before the reverse conducting diode enters a blocking state, such that in a dynamic state, in which the reverse conducting diode enters the blocking state, a forward voltage drop of the reverse conducting diode is higher than that of the at least one freewheeling diode;
wherein the reverse conducting transistor is a RC-IGBT or a BIGT, and
wherein the at least one freewheeling diode includes a SiC diode.

2. The semiconductor module of claim 1, wherein the controller is configured for applying a negative potential to the gate when the reverse conducting diode is in a conducting state, and for applying a positive potential to the gate during the gate pulse.

3. The semiconductor module of claim 1, wherein during the static state, a resistance of the reverse conducting diode is smaller than a resistance of the at least one freewheeling diode.

4. The semiconductor module of claim 1, comprising:
more than one freewheeling diode connected antiparallel with the transistor.

5. The semiconductor module of claim 1, wherein the at least one freewheeling diode antiparallel to the transistor is adjusted to the transistor to minimize switching losses of the semiconductor module in a predefined temperature range.

6. The semiconductor module of claim 1, wherein the at least one freewheeling diode antiparallel to the transistor is adjusted such that in a predefined temperature range at least one of:
during the static state, at least 60% of current will flow through the reverse conducting diode; or
during the dynamic state, at least 60% of the current will flow through the at least one freewheeling diode.

7. The semiconductor module of claim 5, wherein the temperature range is 50° C. to 200° C.

8. The semiconductor module of claim 1, wherein the controller is configured for determining that the reverse conducting diode will switch from a conducting state into a blocking state.

9. The semiconductor module of claim 1, comprising:
a first reverse conducting transistor connected in series with a second reverse conducting transistor, wherein a first DC input is provided by a free end of the first reverse conducting transistor, a second DC input is provided by a free end of the second reverse conducting transistor, and a phase output is provided between the series connected first and second reverse conducting transistors;
wherein the at least one freewheeling diode is connected antiparallel to the first reverse conducting transistor; and
wherein the controller is configured for determining that the reverse conducting diode of the first reverse conducting transistor will switch from a conducting into a blocking state by receiving a switch command for the second reverse conducting transistor.

10. The semiconductor module of claim 9, wherein the controller is configured for switching the second reverse conducting transistor from a turned-off state into a turned-on state by turning a negative potential at the gate of the second reverse conducting transistor into a positive potential at the gate after receiving the switch command.

11. The semiconductor module of claim 9, wherein a pulse length of the gate pulse applied to the first transistor is at least 10% of a length of a turned-off state of the second reverse conducting transistor.

12. The semiconductor module of claim 9, wherein the controller is configured for waiting a blocking time period after the gate pulse before switching the second reverse conducting transistor into a turned-off state.

13. A method for switching a reverse conducting transistor and at least one freewheeling diode connected antiparallel to the transistor, wherein the at least one freewheeling diode has a forward voltage drop higher than a reverse conducting diode of the transistor during a static state, the method comprising:
determining that the reverse conducting diode will switch from a conducting state into a blocking state; and
applying a gate pulse of positive electrical potential to a gate of the transistor before the reverse conducting diode enters a blocking state, such that in a dynamic state, in which the reverse conducting diode enters the blocking state, a forward voltage drop of the reverse conducting diode is higher than that of the at least one freewheeling diode, wherein the reverse conducting transistor is a RC-IGBT or a BIGT, and wherein the at least one freewheeling diode includes a SiC diode.

14. The semiconductor module of claim 2, wherein during the static state, a resistance of the reverse conducting diode is smaller than a resistance of the at least one freewheeling diode.

15. The semiconductor module of claim 2, comprising:
more than one freewheeling diode connected antiparallel with the transistor.

16. The semiconductor module of claim 15, wherein the at least one freewheeling diode antiparallel to the transistor is adjusted to the transistor to minimize switching losses of the semiconductor module in a predefined temperature range.

17. The semiconductor module of claim 16, wherein the at least one freewheeling diode antiparallel to the transistor is adjusted such that in the predefined temperature range at least one of:
during the static state, at least 60% of current will flow through the reverse conducting diode; or
during the dynamic state, at least 60% of the current will flow through the at least one freewheeling diode.

18. The semiconductor module of claim 17, wherein the temperature range is 50° C. to 200° C.

19. The semiconductor module of claim 2, wherein the controller is configured for determining that the reverse conducting diode will switch from a conducting state into a blocking state.

20. The semiconductor module of claim 2, comprising:
a first reverse conducting transistor connected in series with a second reverse conducting transistor, wherein a first DC input is provided by a free end of the first reverse conducting transistor, a second DC input is provided by a free end of the second reverse conducting transistor, and a phase output is provided between the series connected first and second reverse conducting transistors;
wherein the at least one freewheeling diode is connected antiparallel to the first reverse conducting transistor; and
wherein the controller is configured for determining that the reverse conducting diode of the first reverse conducting transistor will switch from a conducting into a blocking state by receiving a switch command for the second reverse conducting transistor.
